(19) United States
(12) Patent Application Publication
(10) Pub. No.: US 2015/0171283 A1
(43) Pub. Date: Jun. 18, 2015

(54) FLUORESCENT MATERIAL AND LIGHT-EMITTING DEVICE

(71) Applicant: Panasonic Intellectual Property Management Co., Ltd., Osaka (JP)

(72) Inventors: KOJIRO OKUYAMA, Nara (JP); SEIGO SHIRAISHI, Osaka (JP)

(21) Appl. No.: 14/633,124

(22) Filed: Feb. 26, 2015

Related U.S. Application Data
(63) Continuation of application No. PCT/JP2014/000558, filed on Feb. 4, 2014.

(30) Foreign Application Priority Data
Apr. 9, 2013 (JP) 2013-081094

(51) Int. Cl. H01L 33/50; C09K 11/77

(52) U.S. Cl. CPC H01L 33/502; C09K 11/7734

(57) ABSTRACT

A fluorescent material forms fluorescent particles and is represented by a general formula of xAO.y₁EuO.y₂EuO_{3/2}.MgO.zSiO₂, wherein, in the general formula, A is at least one selected from Ca, Sr, and Ba; x satisfies 2.80≦x≦3.00; y₁+y₂ satisfies 0.01≦y₁+y₂≦0.20; and z satisfies 1.90≦z≦2.10; and regarding a divalent Eu ratio defined as a content ratio of divalent Eu to all Eu elements, the fluorescent particles have a divalent Eu ratio of 50 mol % or less as measured by X-ray photoelectron spectroscopy, and the fluorescent particles have a divalent Eu ratio of 97 mol % or more as measured by X-ray absorption near-edge structure analysis. A light-emitting device includes a fluorescent layer containing the fluorescent material.

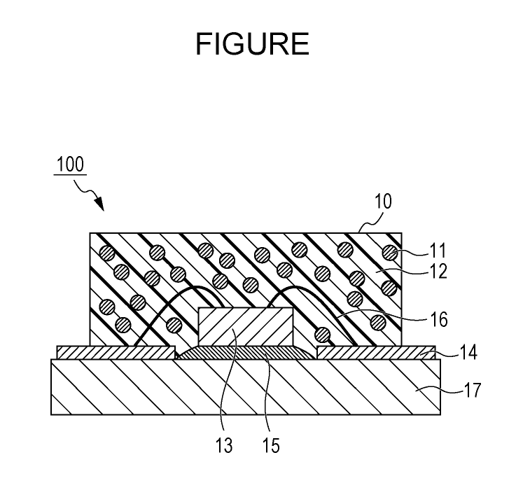

### BACKGROUND

1. Technical Field

The present disclosure relates to a fluorescent material containing Eu element. The present disclosure also relates to a light-emitting device including the fluorescent material.

2. Description of the Related Art

In recent years, white LEDs (light-emitting diodes) have come to be widely used in view of energy conservation. In general, a white LED includes a blue LED chip serving as a blue light-emitting element and a fluorescent material; the blue LED chip emits blue light and a portion of this blue light is changed in terms of color by the fluorescent material and emitted from the fluorescent material; and the blue light from the blue LED chip is mixed with the light emitted from the fluorescent material, so that white light is produced.

Typically, white LEDs are constituted by a combination of a blue LED chip and a yellow fluorescent material. However, in order to achieve good properties in terms of, for example, color rendering and color reproducibility, development is underway of another type of white LED that is constituted by a combination of an LED configured to emit light in a range from the near-ultraviolet region to the indigo region and three fluorescent materials of a blue fluorescent material, a green fluorescent material, and a red fluorescent material.

For the applications in which high light emission energy is required, such as light sources of projectors and light sources of vehicle-mounted head lamps, development is underway of a light source that is constituted by a combination of an LD (semiconductor laser diode) configured to emit light in a range from the near-ultraviolet region to the indigo region and a fluorescent material.

There is a known blue fluorescent material represented by a general formula of Sr₃MgSi₂O₈:Eu²⁺ (SMS fluorescent material). Use of this fluorescent material as a blue fluorescent material of a white LED has been studied (refer to International Publication No. 2012-033122).

### SUMMARY

However, according to the above-described method, the SMS fluorescent material has a low light-emitting efficiency and hence it is difficult to provide a light-emitting device having a high efficiency. In addition, in the case of a light-emitting device constituted by a combination of an LD and the SMS fluorescent material, an increase in the excitation light energy results in an increase in the temperature of the SMS fluorescent material and a luminance saturation phenomenon, so that the light-emitting efficiency is further decreased.

Accordingly, an embodiment of the present disclosure provides a SMS fluorescent material having a high light-emitting efficiency. Another embodiment of the present disclosure provides a light-emitting device having a high efficiency.

A fluorescent material according to an embodiment of the present disclosure is a fluorescent material forming fluorescent particles and represented by a general formula of xAO.y₁EuO.y₂EuO_{3/2}.MgO.zSiO₂, wherein, in the general formula, A is at least one selected from Ca, Sr, and Ba; x satisfies 2.80≦x≦3.00; y₁+y₂ satisfies 0.01≦y₁+y₂≦0.20; and z satisfies 1.90≦z≦2.10; and, regarding a divalent Eu ratio defined as a content ratio of divalent Eu to all Eu elements, the fluorescent particles have a divalent Eu ratio of 50 mol % or less as measured by X-ray photoelectron spectroscopy, and the fluorescent particles have a divalent Eu ratio of 97 mol % or more as measured by X-ray absorption near-edge structure analysis.

A light-emitting device according to an embodiment of the present disclosure includes a fluorescent layer containing the above-described fluorescent material.

An embodiment of the present disclosure provides a SMS fluorescent material having a high light-emitting efficiency. A light-emitting device including this fluorescent material has a high efficiency.

### BRIEF DESCRIPTION OF THE DRAWING

FIGURE is a schematic sectional view of a light-emitting device according to an embodiment of the present disclosure.

### DETAILED DESCRIPTION OF THE EMBODIMENTS

A fluorescent material according to a first aspect of the present disclosure forms fluorescent particles and is represented by a general formula of xAO.y₁EuO.y₂EuO_{3/2}.MgO.zSiO₂. In the general formula, A is at least one selected from Ca, Sr, and Ba; x satisfies 2.80≦x≦3.00; y₁+y₂ satisfies 0.01≦y₁+y₂≦0.20; and z satisfies 1.90≦z≦2.10. Regarding a divalent Eu ratio defined as a content ratio of divalent Eu to all Eu elements, the fluorescent particles have a divalent Eu ratio of 50 mol % or less as measured by X-ray photoelectron spectroscopy; and the fluorescent particles have a divalent Eu ratio of 97 mol % or more as measured by X-ray absorption near-edge structure analysis.

Regarding a fluorescent material according to a second aspect of the present disclosure, in the fluorescent material according to the first aspect, A has a Sr content of 90 mol % or more.

Regarding a fluorescent material according to a third aspect of the present disclosure, in the fluorescent material according to the first aspect, A has a Ba content of 90 mol % or more.

Regarding a fluorescent material according to a fourth aspect of the present disclosure, in the fluorescent material according to any one of the first to third aspects, x is 2.90 or more.

Regarding a fluorescent material according to a fifth aspect of the present disclosure, in the fluorescent material according to any one of the first to fourth aspects, y₁+y₂ is 0.06 or less.

Regarding a fluorescent material according to a sixth aspect of the present disclosure, in the fluorescent material according to any one of the first to fifth aspects, z is 2.00 or more.

Regarding a fluorescent material according to a seventh aspect of the present disclosure, in the fluorescent material according to any one of the first to sixth aspects, the fluorescent particles have a divalent Eu ratio of 36 mol % or less as measured by X-ray photoelectron spectroscopy.

Regarding a fluorescent material according to an eighth aspect of the present disclosure, in the fluorescent material according to any one of the first to seventh aspects, the fluorescent particles have a divalent Eu ratio of 99 mol % or more as measured by X-ray absorption near-edge structure analysis.

Regarding a fluorescent material according to a ninth aspect of the present disclosure, in the fluorescent material according to any one of the first to eighth aspects, the fluorescent particles have a divalent Eu ratio of 13 mol % or more as measured by X-ray photoelectron spectroscopy.

Regarding a fluorescent material according to a tenth aspect of the present disclosure, in the fluorescent material according to any one of the first to ninth aspects, the fluorescent particles have a divalent Eu ratio of less than 100 mol % as measured by X-ray absorption near-edge structure analysis.

A light-emitting device according to an eleventh aspect of the present disclosure includes a fluorescent layer containing the fluorescent material according to any one of the first to tenth aspects.

Regarding a light-emitting device according to a twelfth aspect of the present disclosure, the light-emitting device according to the eleventh aspect further includes a semiconductor light-emitting element configured to emit light having a peak wavelength in a range of 380 to 420 nm, wherein the fluorescent material of the fluorescent layer is configured to partially absorb light emitted from the semiconductor light-emitting element and to emit light having a longer peak wavelength than the absorbed light.

Regarding a light-emitting device according to a thirteenth aspect of the present disclosure, in the light-emitting device according to the twelfth aspect, the semiconductor light-emitting element includes a light-emitting layer formed of a gallium nitride compound semiconductor.

Hereinafter, embodiments according to the present disclosure will be described in detail.

### Fluorescent Material

A fluorescent material according to an embodiment of the present disclosure forms fluorescent particles and is represented by a general formula of xAO.y₁EuO.y₂EuO_{3/2}.MgO.zSiO₂. In the general formula, A is at least one selected from Ca, Sr, and Ba; x satisfies 2.80≦x≦3.00; y₁+y₂ satisfies 0.01≦y₁+y₂≦0.20; and z satisfies 1.90≦z≦2.10.

In addition, regarding this fluorescent material, the fluorescent particles have a divalent Eu ratio of 50 mol % or less as measured by X-ray photoelectron spectroscopy, and the fluorescent particles have a divalent Eu ratio of 97 mol % or more as measured by X-ray absorption near-edge structure analysis. In the present disclosure, the divalent Eu ratio is defined as a content ratio of divalent Eu to all Eu elements.

The X-ray photoelectron spectroscopy (XPS) is a surface analysis method of irradiating the surface of a sample with an X-ray having a known wavelength (for example, Al-Kα radiation, energy: 1487 eV) and measuring the energy of photoelectrons emitted from the sample. In general, XPS allows selective analysis from the sample surface to a depth of about 4 nm. Accordingly, in the present disclosure, the divalent Eu ratio of fluorescent particles as measured by XPS is, for example, an average value of regions from the surfaces of fluorescent particles to a depth of about 4 nm toward the centers.

On the other hand, the X-ray absorption near-edge structure analysis (XANES) is one of the methods (XAFS) of irradiating a sample with X-rays and analyzing the absorption spectrum of the sample. Analysis of an absorption near-edge structure by XANES indicates the state of electrons of atoms absorbing X-rays. In the present disclosure, the divalent Eu ratio of fluorescent particles as measured by XANES is an average value of the whole fluorescent particles. In the case where the divalent Eu ratio of fluorescent particles as measured by XANES is 99% or more, the fluorescent material has a very high light-emitting efficiency.

In existing SMS fluorescent materials, since divalent Eu functions as an activator, it has been considered that, the higher the divalent Eu ratio, the higher the light-emitting efficiency. In contrast to this idea, the inventors of the present disclosure have found the following findings: the light-emitting efficiency is enhanced by providing fluorescent particles in which the divalent Eu ratio is low in the near-surface regions of the particles but the divalent Eu ratio of the whole particles is high.

Hereinafter, a method for producing a fluorescent material according to an embodiment of the present disclosure will be described. However, a method for producing a fluorescent material according to the present disclosure is not limited to the method described below.

In an embodiment of the present disclosure, examples of a strontium source material for a fluorescent material include strontium compounds having a high purity (for example, 99% or more) that can be turned into strontium oxide by firing, such as strontium hydroxide, strontium carbonate, strontium nitrate, strontium halide, and strontium oxalate; and strontium oxide having a high purity (for example, 99% or more).

Examples of a calcium source material for a fluorescent material include calcium compounds having a high purity (for example, 99% or more) that can be turned into calcium oxide by firing, such as calcium hydroxide, calcium carbonate, calcium nitrate, calcium halide, and calcium oxalate; and calcium oxide having a high purity (for example, 99% or more).

Examples of a barium source material for a fluorescent material include barium compounds having a high purity (for example, 99% or more) that can be turned into barium oxide by firing, such as barium hydroxide, barium carbonate, barium nitrate, barium halide, and barium oxalate; and barium oxide having a high purity (for example, 99% or more).

Examples of a magnesium source material for a fluorescent material include magnesium compounds having a high purity (for example, 99% or more) that can be turned into magnesium oxide by firing, such as magnesium hydroxide, magnesium carbonate, magnesium nitrate, magnesium halide, magnesium oxalate, and basic magnesium carbonate; and magnesium oxide having a high purity (for example, 99% or more).

Examples of a europium source material for a fluorescent material include europium compounds having a high purity (for example, 99% or more) that can be turned into europium oxide by firing, such as europium hydroxide, europium carbonate, europium nitrate, europium halide, and europium oxalate; and europium oxide having a high purity (for example, 99% or more).

A silicon source material can be selected from various oxide materials.

In order to promote a reaction, a small amount of a fluoride (such as aluminum fluoride) or a chloride (such as calcium chloride) is desirably added.

There is a correlation between the average particle size of source materials and the divalent Eu ratio of the whole fluorescent particles. In particular, the larger the average particle size of the silicon source material, the higher the divalent Eu ratio of the whole fluorescent particles. Accordingly, by selecting the average particle size of the silicon source material, the divalent Eu ratio of the whole fluorescent particles can be controlled. In order to adjust the average particle size of the silicon source material, for example, a known pulverization method and a classification method such as sieving can be appropriately employed.

Source materials can be mixed by wet mixing in a solution or by dry mixing of dry powders, with an apparatus normally used in industry, such as a ball mill, a media mixer, a planetary mill, a vibration mill, a jet mill, a V-type mixer, or a stirrer.

The resultant powder mixture is fired in a temperature range of 1100° C. to 1500° C. for about 1 to about 10 hours. In order to control the divalent Eu ratio of the surfaces of the fluorescent particles and the divalent Eu ratio of the whole fluorescent particles, firing is performed in an atmosphere containing oxygen and hydrogen such as a gas mixture containing nitrogen, hydrogen, and oxygen, and the oxygen partial pressure in the gas mixture is accurately controlled. The lower the oxygen partial pressure in the gas mixture, the higher the divalent Eu ratio of fluorescent particles, in particular, the surfaces of fluorescent particles.

The firing can be performed with a furnace normally used in industry, such as a continuous or batch electric furnace or gas furnace, for example, a pusher furnace.

In the case of using a source material that can be turned into oxide by firing, such as hydroxide, carbonate, nitrate, halide, or oxalate, the source material can be calcined in a temperature range of 800° C. to 1400° C. prior to the firing.

The resultant fluorescent powder is pulverized again with a ball mill, a jet mill, or the like, and, if necessary, washed or classified, to thereby control the particle size distribution and flowability of the fluorescent powder.

A fluorescent material according to an embodiment of the present disclosure has a higher light-emitting efficiency than the existing SMS fluorescent material. Accordingly, application of this fluorescent material according to an embodiment of the present disclosure to a light-emitting device including a fluorescent layer can provide a light-emitting device having a high efficiency.

### Light-Emitting Device

A light-emitting device according to an embodiment of the present disclosure includes a fluorescent layer containing the above-described fluorescent material according to an embodiment of the present disclosure. Examples of the light-emitting device include devices employing a combination of a light-emitting diode (LED) or a semiconductor laser diode (LD) and one or more fluorescent materials, such as light sources of projectors, light sources of vehicle-mounted head lamps, and light sources of white LED lighting devices; and devices employing one or more fluorescent materials, such as sensors, amplifiers, and plasma display panels (PDPs).

Hereinafter, an example of the configuration of a light-emitting device according to an embodiment of the present disclosure will be specifically described with reference to FIGURE. However, the configuration of a light-emitting device according to an embodiment of the present disclosure is not limited to the following configuration.

FIGURE is a schematic sectional view of a light-emitting device according to an embodiment of the present disclosure.

A light-emitting device 100 includes a fluorescent layer in which fluorescent materials 11 are dispersed in a resin 12, and further includes a semiconductor light-emitting element 13. The semiconductor light-emitting element 13 is fixed to a substrate 17 with a die bonding material 15 therebetween. The semiconductor light-emitting element 13 is electrically connected to electrodes 14 via bonding wires 16. Application of a predetermined voltage to the electrodes 14 causes the semiconductor light-emitting element 13 to emit light having a peak wavelength in a range of 380 to 420 nm (in other words, light in a range from the near-ultraviolet region to the indigo region). The semiconductor light-emitting element 13 may be, for example, a semiconductor light-emitting element including a light-emitting layer formed of a gallium nitride compound semiconductor. The fluorescent materials 11 partially absorb light emitted from the semiconductor light-emitting element 13 and emit light having a longer peak wavelength than the absorbed light. The fluorescent materials 11 include the above-described fluorescent material according to an embodiment as a blue fluorescent material, and further include a yellow fluorescent material. Thus, a mixture of the above-described fluorescent material according to an embodiment and the yellow fluorescent material is used as the fluorescent materials 11. As a result, mixing of blue light and yellow light occurs, so that the light-emitting device 100 emits white light. The fluorescent materials 11 are not limited to the above-described example. For example, the fluorescent materials 11 may be a mixture of the above-described fluorescent material according to an embodiment as a blue fluorescent material, a green fluorescent material, and a red fluorescent material. For example, the yellow fluorescent material, the green fluorescent material, and the red fluorescent material can be selected from known fluorescent materials.

### EXAMPLES

Hereinafter, fluorescent materials according to embodiments of the present disclosure will be described in detail with reference to Examples and Comparative examples. However, fluorescent materials according to the present disclosure are not limited to these Examples.

### Production Examples of Fluorescent Materials

The following starting materials were weighed so as to achieve a predetermined composition and subjected to wet mixing in pure water with a ball mill: SrCO₃ (purity: 99.9%, average particle size: 1 μm), BaCO₃ (purity: 99.9%, average particle size: 1 μm), CaCO₃ (purity: 99.9%, average particle size: 1 μm), Eu₂O₃ (purity: 99.9%, average particle size: 1 μm), MgCO₃ (purity: 99.9%, average particle size: 0.5 μm), and SiO₂ (purity: 99.9%, average particle size: 1 to 12 μm, spherical particles).

The resultant mixture was dried at 150° C. for 10 hours and the resultant dry powder was calcined in the air at 1100° C. for 4 hours. The resultant calcined substance was fired in a gas mixture containing nitrogen, hydrogen, and oxygen at 1200° C. to 1400° C. for 4 hours, and further fired at 1200° C. to 1300° C. for 24 hours to thereby provide a fluorescent material. During the firing, the oxygen partial pressure in the gas mixture was accurately controlled to thereby adjust the divalent Eu ratio of the fluorescent particles. In the case of controlling the oxygen partial pressure to 10⁻¹⁶ atm, the surfaces of the fluorescent particles had a divalent Eu ratio of 80%; in the case of controlling the oxygen partial pressure to 10^{-15.5} atm, the surfaces of the fluorescent particles had a divalent Eu ratio of 50%; in the case of controlling the oxygen partial pressure to 10^{-14.5} atm, the surfaces of the fluorescent particles had a divalent Eu ratio of 20%; and, in the case of controlling the oxygen partial pressure to 10⁻¹² atm, the surfaces of the fluorescent particles had a divalent Eu ratio of 10%. On the one hand, the divalent Eu ratio of the surfaces of the fluorescent particles was thus determined only by the oxygen partial pressure in the gas mixture. On the other hand, the divalent Eu ratio of the whole fluorescent particles was adjusted by further controlling the average particle size of the SiO₂ starting material. The larger the average particle size of the SiO₂ starting material, the higher the divalent Eu ratio of the whole fluorescent particles becomes. Under an oxygen partial pressure of 10^{-15.5} atm in the gas mixture, in the case of using the SiO₂ starting material having an average particle size of 1 μm, the whole fluorescent particles had a divalent Eu ratio of 93%; in the case of using the SiO₂ starting material having an average particle size of 4 μm, the whole fluorescent particles had a divalent Eu ratio of 97%; and, in the case of using the SiO₂ starting material having an average particle size of 9 μm, the whole fluorescent particles had a divalent Eu ratio of 99%.

The divalent Eu ratio of the surfaces of the fluorescent particles was calculated by XPS (with Quantera SXM, manufactured by ULVAC-PHI, Inc.) as a peak intensity ratio from a peak due to Eu²⁺ and a peak due to Eu³⁺ (in other words, a peak area ratio). In this calculation, background subtraction was performed by the Shirley method and peak fitting was performed with a Gaussian function. The divalent Eu ratio of the whole fluorescent particles was determined in the following manner: in a XANES spectrum obtained with BL01B1 in SPring-8, which is a large synchrotron radiation facility, a peak due to Eu²⁺ and a peak due to Eu³⁺ were separated and the divalent Eu ratio was calculated from the areas of these peaks.

Table 1 below summarizes composition proportions of the fluorescent materials, the divalent Eu ratios of the surfaces of the particles, the divalent Eu ratios of the whole particles, and number ratios of light quantums of samples irradiated with indigo light having a peak wavelength of 405 nm emitted from an LD at 1 W and at 10 W. The number ratios of light quantums are expressed as values relative to the number of light quantums of Ba_{0.7}Eu_{0.3}MgAl₁₀O₁₇ serving as a standard sample. In Table 1, samples marked with * are Comparative examples, whereas samples without * are Examples.

TABLE 1

| | | | | | Divalent Eu ratio | | Number ratio of light | |
|---|---|---|---|---|---|---|---|---|
| | | | | | (%) | | quantums (%) | |
| Sample | | | | | Particle | Whole | Emission | Emission |
| No. | A | x | y₁ + y₂ | z | surfaces | particles | at 1 W | at 10 W |
| *1 | Sr | 3.10 | 0.005 | 2.00 | 48 | 97 | 67 | 58 |
| *2 | Sr | 2.70 | 0.30 | 2.00 | 42 | 97 | 98 | 72 |
| *3 | Sr | 2.99 | 0.01 | 2.30 | 35 | 97 | 95 | 88 |
| *4 | Sr | 2.90 | 0.10 | 2.00 | 80 | 99 | 99 | 90 |
| *5 | Sr | 2.90 | 0.10 | 2.00 | 10 | 93 | 56 | 44 |
| 6 | Sr | 2.90 | 0.10 | 2.00 | 50 | 97 | 112 | 106 |
| 7 | Sr | 2.90 | 0.10 | 2.00 | 25 | 98 | 114 | 109 |
| 8 | Sr | 2.90 | 0.10 | 2.00 | 20 | 99 | 132 | 128 |
| 9 | Sr | 2.91 | 0.09 | 2.05 | 18 | 99 | 125 | 121 |
| 10 | Sr | 2.90 | 0.10 | 2.10 | 15 | 99 | 129 | 124 |
| 11 | Sr | 2.90 | 0.10 | 1.90 | 17 | 98 | 113 | 109 |
| 12 | Sr | 2.80 | 0.20 | 2.00 | 38 | 99 | 119 | 113 |
| 13 | Sr | 3.00 | 0.01 | 2.00 | 50 | 99 | 121 | 118 |
| 14 | Sr | 2.94 | 0.06 | 2.00 | 36 | 99 | 135 | 134 |
| 15 | Sr | 2.94 | 0.06 | 2.00 | 22 | 99 | 137 | 134 |
| 16 | Sr | 2.94 | 0.06 | 2.00 | 13 | 99 | 130 | 125 |
| 17 | Sr_{0.95}Ca_{0.05} | 2.94 | 0.06 | 2.00 | 31 | 99 | 120 | 119 |
| 18 | Sr_{0.90}Ba_{0.10} | 2.94 | 0.06 | 2.00 | 25 | 99 | 132 | 130 |
| *19 | Sr_{0.90}Ba_{0.10} | 2.94 | 0.06 | 2.00 | 12 | 95 | 78 | 70 |
| 20 | Sr_{0.30}Ba_{0.70} | 2.94 | 0.06 | 2.00 | 22 | 99 | 126 | 124 |
| 21 | Sr_{0.10}Ba_{0.90} | 2.94 | 0.06 | 2.00 | 24 | 99 | 130 | 126 |
| 22 | Sr_{0.05}Ba_{0.95} | 2.94 | 0.06 | 2.00 | 22 | 99 | 135 | 129 |
| 23 | Ba | 2.94 | 0.06 | 2.00 | 30 | 99 | 122 | 113 |
| Standard | Ba_{0.7}Eu_{0.3}MgAl₁₀O₁₇ | | | | | | 100 | 88 |
| sample | | | | | | | | |

As is obvious from Table 1, the fluorescent materials of Examples (satisfying conditions of embodiments according to the present disclosure in terms of composition proportions, the divalent Eu ratios of the surfaces of particles, and the divalent Eu ratios of the whole particles) all have high number ratios of light quantums upon irradiation with indigo light at 405 nm and a decrease in the number ratio of light quantums due to an increase in the energy of the excitation light is small. In particular, the number ratios of light quantums are high in fluorescent materials in which the divalent Eu ratios of the surfaces of particles is 50% or less and the divalent Eu ratios of the whole particles is 99% or more (Sample Nos. 8 to 10, 12 to 18, and 20 to 23).

### Production of Light-Emitting Devices

Fluorescent materials were prepared as in Sample Nos. 2 to 6, 8, 14 to 16, 18, and 21. Each of these fluorescent materials and a dimethyl silicone resin were kneaded with a three-roll kneader to provide a mixture. This mixture was filled into a mold, defoamed by vacuum defoaming, then combined with a semiconductor light-emitting element (gallium nitride, 600 μm sides, peak wavelength: 405 nm) wired on a substrate, and preliminarily cured by heating at 150° C. for 10 minutes. The mixture was released from the mold and then cured by heating at 150° C. for 4 hours. Thus, a light-emitting device illustrated in FIGURE was obtained. The weight content of the fluorescent material in the mixture of the fluorescent material and the resin was set to 50% by weight.

A light-emitting efficiency of each of the samples of Examples and Comparative examples was measured by applying a current of 500 mA with a pulse width of 30 ms and by measuring blue light emitted from the sample with a total luminous flux measurement system (HM φ300 mm).

Table 2 below summarizes fluorescent materials (Sample Nos. 2 to 6, 8, 14 to 16, 18, and 21) used in light-emitting devices and the light-emitting efficiency of the samples measured in the above-described manner. The light-emitting efficiency is expressed as values relative to the light-emitting efficiency of a standard sample (Ba_{0.7}Eu_{0.3}MgAl₁₀O₁₇). In Table 2, samples marked with * are Comparative examples, whereas samples without * are Examples.

TABLE 2

| | | Light-emitting efficiency |
|---|---|---|
| Sample No. | Fluorescent material | relative value (%) |
| *24 | Sample No. 2 | 96 |
| *25 | Sample No. 3 | 92 |
| *26 | Sample No. 4 | 99 |
| *27 | Sample No. 5 | 60 |
| 28 | Sample No. 6 | 116 |
| 29 | Sample No. 8 | 133 |
| 30 | Sample No. 14 | 138 |
| 31 | Sample No. 15 | 137 |
| 32 | Sample No. 16 | 128 |
| 33 | Sample No. 18 | 134 |
| 34 | Sample No. 21 | 136 |
| Standard | Ba_{0.7}Eu_{0.3}MgAl₁₀O₁₇ | 100 |
| sample | | |

As is obvious from Table 2, the light-emitting devices of Examples (satisfying conditions of embodiments according to the present disclosure) have a high light-emitting efficiency.

A light-emitting device including a fluorescent layer containing a fluorescent material according to an embodiment of the present disclosure is highly efficient and hence is useful in various applications. Specifically, the light-emitting device can be used in applications including devices employing a combination of a light-emitting diode (LED) or a semiconductor laser diode (LD) and one or more fluorescent materials, such as light sources of projectors, light sources of vehicle-mounted head lamps, and light sources of white LED lighting devices; and devices employing a fluorescent material, such as sensors, amplifiers, and plasma display panels (PDPs).

What is claimed is:

1. A fluorescent material forming fluorescent particles and represented by a general formula of xAO.y₁EuO.y₂EuO_{3/2}.MgO.zSiO₂,
wherein, in the general formula, A is at least one selected from Ca, Sr, and Ba; x satisfies 2.80≦x≦3.00; y₁+y₂ satisfies 0.01≦y₁+y₂≦0.20; and z satisfies 1.90≦z≦2.10; and
regarding a divalent Eu ratio defined as a content ratio of divalent Eu to all Eu elements, the fluorescent particles have a divalent Eu ratio of 50 mol % or less as measured by X-ray photoelectron spectroscopy, and the fluorescent particles have a divalent Eu ratio of 97 mol % or more as measured by X-ray absorption near-edge structure analysis.

2. The fluorescent material according to claim 1, wherein A has a Sr content of 90 mol % or more.

3. The fluorescent material according to claim 1, wherein A has a Ba content of 90 mol % or more.

4. The fluorescent material according to claim 1, wherein x is 2.90 or more.

5. The fluorescent material according to claim 1, wherein y₁+y₂ is 0.06 or less.

6. The fluorescent material according to claim 1, wherein z is 2.00 or more.

7. The fluorescent material according to claim 1, wherein the fluorescent particles have a divalent Eu ratio of 36 mol % or less as measured by the X-ray photoelectron spectroscopy.

8. The fluorescent material according to claim 1, wherein the fluorescent particles have a divalent Eu ratio of 99 mol % or more as measured by the X-ray absorption near-edge structure analysis.

9. The fluorescent material according to claim 7, wherein the fluorescent particles have a divalent Eu ratio of 13 mol % or more as measured by the X-ray photoelectron spectroscopy.

10. The fluorescent material according to claim 8, wherein the fluorescent particles have a divalent Eu ratio of less than 100 mol % as measured by the X-ray absorption near-edge structure analysis.

11. A light-emitting device comprising a fluorescent layer containing a forming fluorescent particles and represented by a general formula of xAO.y₁EuO.y₂EuO_{3/2}.MgO.zSiO₂,
wherein, in the general formula, A is at least one selected from Ca, Sr, and Ba; x satisfies 2.80≦x≦3.00; y₁+y₂ satisfies 0.01≦y₁+y₂≦0.20; and z satisfies 1.90≦z≦2.10; and
regarding a divalent Eu ratio defined as a content ratio of divalent Eu to all Eu elements, the fluorescent particles have a divalent Eu ratio of 50 mol % or less as measured by X-ray photoelectron spectroscopy, and the fluorescent particles have a divalent Eu ratio of 97 mol % or more as measured by X-ray absorption near-edge structure analysis.

12. The light-emitting device according to claim 11, further comprising a semiconductor light-emitting element that emits light having a peak wavelength in a range of 380 to 420 nm, wherein the fluorescent material of the fluorescent layer partially absorbs light emitted from the semiconductor light-emitting element and emits light having a longer peak wavelength than the absorbed light.

13. The light-emitting device according to claim 12, wherein the semiconductor light-emitting element includes a light-emitting layer formed of a gallium nitride compound semiconductor.
